(19) United States
(12) Patent Application Publication
(10) Pub. No.: US 2014/0246078 A1
(43) Pub. Date: Sep. 4, 2014

(54) COMPOSITE INSULATING PANEL

(71) Applicant: KINGSPAN HOLDINGS (IRL) LIMITED, County Cavan (IE)

(72) Inventors: James Carolan, Kingscourt (IE); Gregory Flynn, Collon (IE)

(21) Appl. No.: 14/348,687

(22) PCT Filed: Oct. 1, 2012
(86) PCT No.: PCT/IE2012/000044

§ 371 Date: Mar. 31, 2014

(30) Foreign Application Priority Data
Sep. 30, 2011 (IE) 2011/0444
Mar. 8, 2012 (IE) 2012-0124

(51) Int. Cl. H01L 31/042; H01L 31/048

(52) U.S. Cl. CPC H01L 31/0422; H01L 31/0482
USPC 136/251

(57) ABSTRACT

A composite insulating panel comprises an external sheet, an internal sheet, and an insulating body between the external sheet and the internal sheet. There is a photovoltaic solar collector module on the external surface of the external sheet and a connector for interconnecting between the photovoltaic solar collector module and another photovoltaic solar collector module. The panel has a through hole for receiving a housing, of the connector.

With increasing energy costs there is a need for a more thermally efficient system for cladding a building.

This invention is directed towards providing an improved insulating panel which will address this issue.

### STATEMENTS OF INVENTION

According to the invention there is provided a composite insulating panel comprising:- an external sheet; an internal sheet; an insulating body between the external sheet and the internal sheet, a photovoltaic solar collector module on the external surface of the external sheet, and a connector for interconnecting between the photovoltaic solar collector module and another photovoltaic solar collector module, and a housing for the connector, the panel having a through hole for receiving the housing.

In one embodiment the housing comprises an external part which extends into the panel hole from the external sheet and an internal part which extends into the panel hole from the internal sheet.

In one embodiment the external housing part has means such as a flange to prevent the housing part from passing completely through the hole in the panel. The external housing part may have clipping means for engagement in the panel hole.

In one case the internal housing part has means such as a flange to prevent the housing part from passing completely through the hole in the panel.

In one case the connector comprises external terminals for connection with photovoltaic cells and wire connections extending through the panel from the terminals. The wires may have a spiral form. The connector may comprise internal terminals. The connector may comprise internal sockets to which the internal terminals are connected.

In one embodiment the external sheet comprises a plurality of longitudinally extending ribs.

In one case the photovoltaic sheet follows the contours of the ribs.

In one embodiment the panel comprises a plurality of photovoltaic solar collector sheets laminated to the external sheet of the panel. The photovoltaic sheets may be spaced-apart along and/or across the external sheet of the panel, at least some of the photovoltaic sheets being electrically interconnected.

The external sheet of the panel may comprise a plurality of raised projections and the photovoltaic sheets are located between the projections. The raised projections may extend longitudinally along the length of the panel. In one case the raised projections comprise raised crowns. The raised crowns may be of generally trapezoidal form.

The raised projections may comprise a side underlap projection and a side overlap projection for jointing adjacent panels.

In another embodiment the external sheet comprises a first longitudinally extending raised projection at one side of the panel, a second longitudinally extending raised projection at an opposite side of the panel and a substantially flat portion extending between the first and second raised projection; and the a photovoltaic solar collector sheet is laminated to the external surface of the flat portion of the external sheet.

The external sheet may comprise a male projecting part and a female recess part for jointing adjacent panels.

The internal sheet may comprise a male projecting part and a female recess part for jointing adjacent panels.

In one embodiment the insulating body comprises a foam such as a polyisocyanurate foam material or a phenolic foam material.

In one case the external sheet comprises a steel material.

In one case the internal sheet comprises a metallic material such as a steel material.

The panel may comprise a roof panel.

The invention also provides roof assembly comprising a plurality of panels of the invention.

According to the invention there is provided a panel comprising:
an external sheet having a first longitudinally extending raised projection at one side of the panel, a second longitudinally extending raised projection at an opposite side of the panel and a substantially flat portion extending between the first and second raised projection; and
a photovoltaic solar collector sheet laminated to the external surface of the flat portion of the external sheet.

According to the invention there is also provided a composite insulating panel comprising:
an external sheet;
an internal sheet;
an insulating body between the external sheet and the internal sheet, and
the external sheet having a first longitudinally extending raised projection at one side of the panel, a second longitudinally extending raised projection at an opposite side of the panel and a substantially flat portion extending between the first and second raised projection; and
a photovoltaic solar collector sheet laminated to the external surface of the flat portion of the external sheet.

Preferably there is a translucent cover for the photovoltaic sheet.

In one case the panel comprises an adhesive layer between the photovoltaic sheet and the cover.

In one embodiment there is an adhesive layer between the photovoltaic sheet and the external sheet.

In one case the solar collector comprises a photovoltaic sheet, a translucent cover for the photovoltaic sheet, a first adhesive layer between one side of the photovoltaic sheet and the cover layer, and a second adhesive layer on the other side of the photovoltaic sheet.

In one embodiment the second adhesive layer comprises a thermoplastic polyurethane (TPU) adhesive.

The first adhesive layer may be of a hot melt adhesive such as ethylene vinyl acetate (EVA) material.

In one case the translucent cover is of a plastics material such as ethylene tetrafluoroethylene material.

In one embodiment the composite insulating panel comprises a connector for interconnecting between the photovoltaic solar collector module and another photovoltaic solar collector module or another element, and a housing for the connector, the panel having a through hole for receiving the housing.

In one embodiment the housing comprises an external part which extends into the panel hole from the external sheet and an internal part which extends into the panel hole from the internal sheet.

In one case the connector comprises external terminals for connection with photovoltaic cells and wire connections extending through the panel from the terminals. The connector may comprise internal terminals. The connector may comprise internal sockets to which the internal terminals are connected.

In one embodiment the external terminals are overlayed by a cover layer. The panel advantageously comprises a single connector.

In one embodiment the panel comprises a plurality of photovoltaic solar collector sheets laminated to the external sheet of the panel. The photovoltaic sheets may be spaced-apart along and/or across the external sheet of the panel, at least some of the photovoltaic sheets being electrically interconnected.

In one embodiment the raised projections comprise raised crowns. In one case the raised projections are of generally trapezoidal form and extend longitudinally along the length of the panel. The raised projections may comprise a side underlap projection and a side overlap projection for jointing adjacent like panels.

The raised projections may comprise a side underlap projection and a side overlap projection for jointing adjacent panels.

In one case the external sheet comprises a male projecting part and a female recess part for jointing adjacent panels.

The internal sheet may comprise a male projecting part and a female recess part for jointing adjacent panels.

In a preferred embodiment the insulating body comprises a foam such as a polyisocyanurate foam material, or a phenolic foam material.

In one embodiment the external sheet comprises a metallic material, such as a steel material.

In one embodiment the internal sheet comprises a metallic material, such as a steel material.

In one case the panel comprises a roof panel.

The invention also provides a roof assembly comprising a plurality of composite panels of the invention.

The invention also provides a method for manufacturing a composite insulated panel with a photovoltaic solar collector sheet attached thereto comprising the steps of:
providing a panel comprising:
   an external sheet, the external sheet having a first longitudinally extending raised projection at one side of the panel, a second longitudinally extending raised projection at an opposite side of the panel and a substantially flat portion extending between the first and second raised projection; and
   laminating a solar collector sheet to the external surface of the flat portion of the external sheet of the panel.

The invention further provides a method for manufacturing a composite insulated panel with a photovoltaic solar collector sheet attached thereto comprising the steps of:
providing a panel comprising:
an external sheet;
an internal sheet; and
an insulating body between the external sheet and the internal sheet, and
the external sheet having a first longitudinally extending raised projection at one side of the panel, a second longitudinally extending raised projection at an opposite side of the panel and a substantially flat portion extending between the first and second raised projection; and
laminating a solar collector sheet to the external surface of the flat portion of the external sheet of the panel.

In one embodiment the method comprises providing a first adhesive sheet between the external sheet of the panel and the solar collector sheet.

The method may comprise providing a translucent cover sheet over the photovoltaic solar collector sheet and laminating the panel external sheet, solar collector sheet and the translucent cover sheet. A second adhesive sheet may be provided between the solar collector sheet and the translucent cover sheet.

The method may comprise electrically interconnecting at least some of the separate solar collector sheets of adjacent panels.

In one embodiment the method comprises the step, prior to lamination of inserting at least part of a connector through a hole in the panel and electrically connecting the solar collector to the connector. Preferably the method includes the step of covering the connection between the connector and the solar collector with a cover layer, prior to lamination.

### BRIEF DESCRIPTION OF THE DRAWINGS

The invention will be more clearly understood from the following description thereof given by way of example only, in which:

FIG. 1 is a perspective, partially cross sectional view of an insulating panel of the invention;

FIG. 2 is an enlarged cross sectional view of a portion of the panel of FIG. 1;

FIG. 3 is an exploded view of the panel of FIGS. 1 and 2;

FIGS. 4 to 7 are isometric views of various steps used in the manufacture of the panel;

FIG. 8 is another isometric view of the panel of the invention;

FIG. 9 is an isometric view of a photovoltaic solar collector sheet;

FIG. 10 is an exploded view of another panel according to the invention;

FIG. 11 is an isometric, partially cross sectional view of the panel of FIG. 10;

FIG. 12 is an enlarged cross sectional view of portion of the panel of FIG. 11;

FIG. 13 is a perspective view of a panel of the invention with adjacent photovoltaic solar collector sheets mounted thereto at one end;

FIG. 14 is a view similar to FIG. 13 with further photovoltaic solar collector sheets;

FIG. 15 is a view similar to FIG. 14 with further photovoltaic solar collector sheets;

FIG. 16 is a perspective view of an assembly of insulating panels of the invention with photovoltaic solar collector sheets in situ;

FIG. 17 is a diagram illustrating a panel with another arrangement of photovoltaic solar collector sheets;

FIG. 18 is a perspective view of an insulating panel according to the invention;

FIG. 19 is a perspective, partially cross sectional view of the insulating panel of FIG. 1;

FIG. 20 is an enlarged cross sectional view of a portion of the panel of FIG. 1;

FIG. 21 is an exploded view of the panel of FIGS. 1 to 3;

FIGS. 22 to 25 are isometric views of various steps used in the manufacture of the panel;

FIG. 26 is another isometric view of the panel of the invention;

FIG. 27 is an isometric view of two similar panels jointed together;

FIG. 28 is an exploded partially cross sectional view of a connector according to the invention which may be used with any of the panels of FIGS. 1 to 17;

FIG. 29 is an assembled view of the panel and connector of FIG. 28;

FIG. 30 is an exploded perspective view of the connector;

FIG. 31 is an assembled view of the connector of FIG. 30;

FIG. 32 is a perspective view of one part of the connector;

FIG. 33 is a perspective view of part of a panel for reception of the connector;

FIG. 34 is a perspective view from above of part of the connector inserted into the panel;

FIG. 35 is a perspective view from below of part of the connector inserted into the panel;

FIG. 36 is an underneath plan view of the connector of FIG. 35;

FIGS. 37 and 38 are perspective views of terminals of the connector;

FIG. 39 is a perspective view of a tool used in association with the terminals of FIGS. 37 and 38;

FIG. 40 is a perspective view of a field attachable connector;

FIG. 41 is an isometric view of another panel according to the invention; and

FIG. 42 is diagrammatic exploded view of the panel of FIG. 41.

### DETAILED DESCRIPTION

Referring to the drawings there is illustrated an insulating panel 1 according to the invention comprising a first or external sheet 2, a second or inner sheet 4 with an insulating body, in this case an insulating foam 5 therebetween. The foam is in direct contact with the inner faces of both of the sheets 2, 4. The foam may, for example be a polyisocyanurate foam or a phenolic foam. In this case the panel 1 is a roof panel 1 comprising a profiled external sheet 2 which is typically of metal, such as galvanised steel. The profile in this case comprises a plurality of elongate strengthening ribs 30 which extend longitudinally along the length of the external sheet 2. In this case there are also raised crowns 3. The crowns 3 in this case are of generally trapezoidal form and extend longitudinally along the length of the panel. In this case there is a side underlap projection or crown 31 on one side of the upper sheet 2 and a side overlap projection or crown 36 on the opposite side of the panel. In use, adjacent like panels are overlapped by overlapping the overlap crown 36 of one panel with the underlap crown 31 of an adjacent panel. Similarly, the panels typically have end underlap and overlap features for end lapping of adjacent like panels. The inner metal liner sheet 4 may be of painted galvanised steel.

A photovoltaic solar collector unit 10 is mounted to the external sheet 2 of the underlying insulating panel. The solar collector 10 comprises a photovoltaic sheet 20 and a translucent cover 21 for the photovoltaic sheet 20. A first adhesive layer 22 is provided between the photovoltaic sheet 20 and the translucent cover 21. A second adhesive layer 23 is provided between the underside of the photovoltaic sheet 20 and the external surface of the composite panel upper or external sheet 2. The cover 21 is of a suitable protective plastics material such as ethylene tetrafluoroethylene (ETFE) which has a high melting temperature and excellent chemical and electrical resistance properties. It is resilient and self cleaning compared to glass, an ETFE film transmits more light and costs substantially less.

The adhesive layers are preferably of a hot melt adhesive to facilitate lamination. In one case the adhesive layer 22 is of ethylene vinyl acetate (EVA).

For enhanced bond strength the adhesive layer 23 between the external sheet 2 and the photovoltaic sheet 20 comprises a thermoplastic polyurethane (TPU) material.

The composite panel may be manufactured by a process as described in our GB 2309412 A, the entire contents of which are herein incorporated by reference.

The panels are manufactured with the external sheet 2 lowermost. For the next steps in the process of the invention the panels are turned so that the external sheet 2 is uppermost.

In the invention sheets of the photovoltaic 20, the adhesives 22, 23, and the cover 21 are drawn from supply reels, are cut to length, and then laid on top of the upper sheet 2 of the insulated panel. Using a pressure laminating process the various layers are heated and pressed to adhere to and conform to the profile of the outer sheet 2 of the insulated panel including the reinforcing ribs and in this case also the crowns 3.

A composite insulating panel may therefore be fully covered by photovoltaic cells thereby utilising the full panel surface for energy collection.

In the invention, rather than utilising a pre-prepared photovoltaic laminate assembly, some elements of the photovoltaic assembly are used individually and the assembly is laminated to the profiled composite insulating panel in one step. In the invention a separate carrier for the photovoltaic is not required as the photovoltaic is bonded directly to the external sheet of the composite insulating panel.

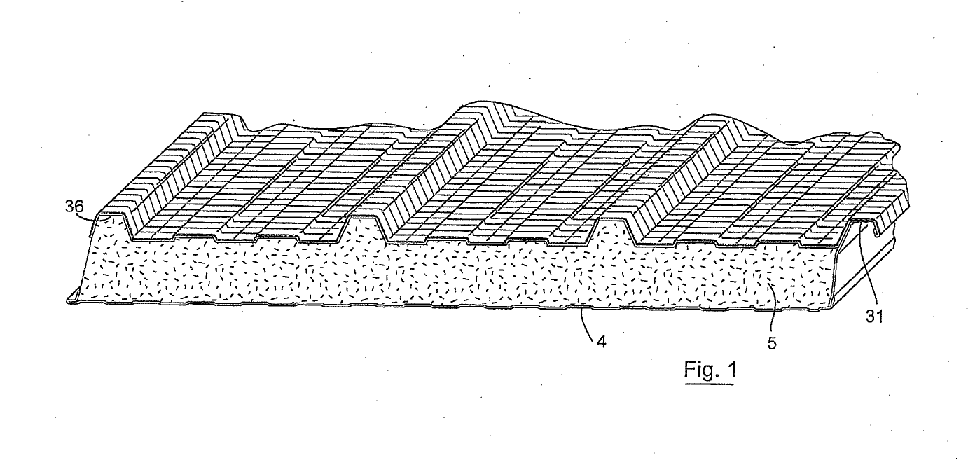

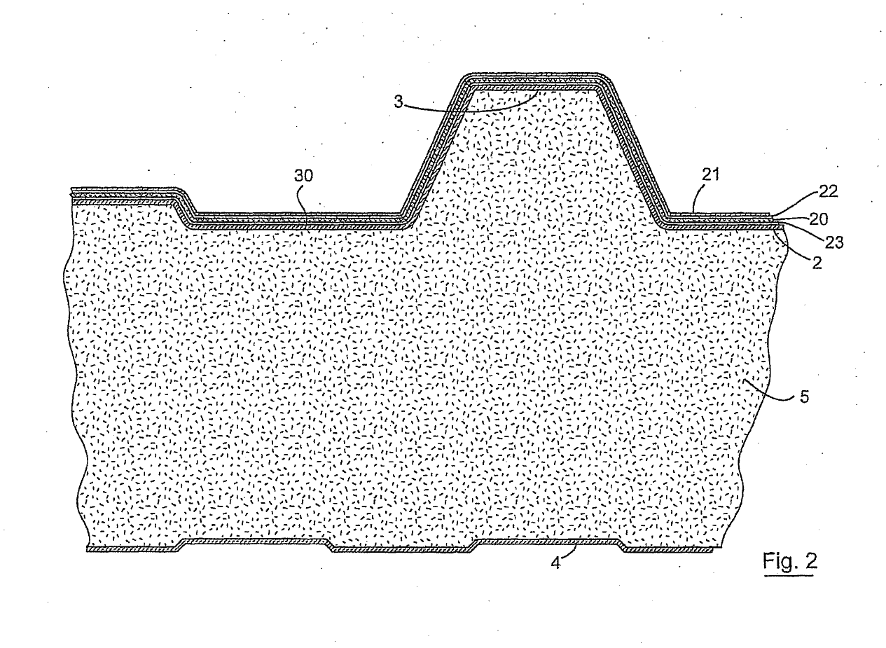

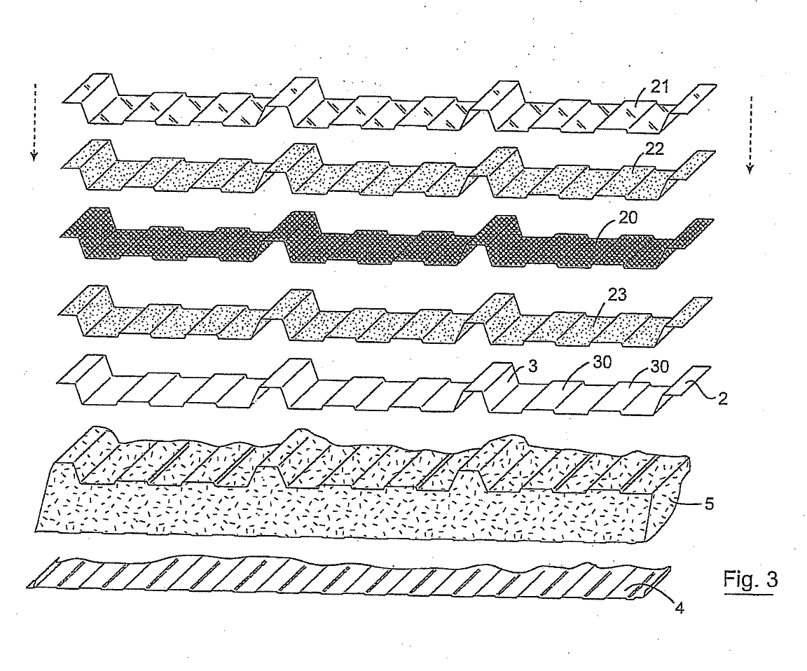

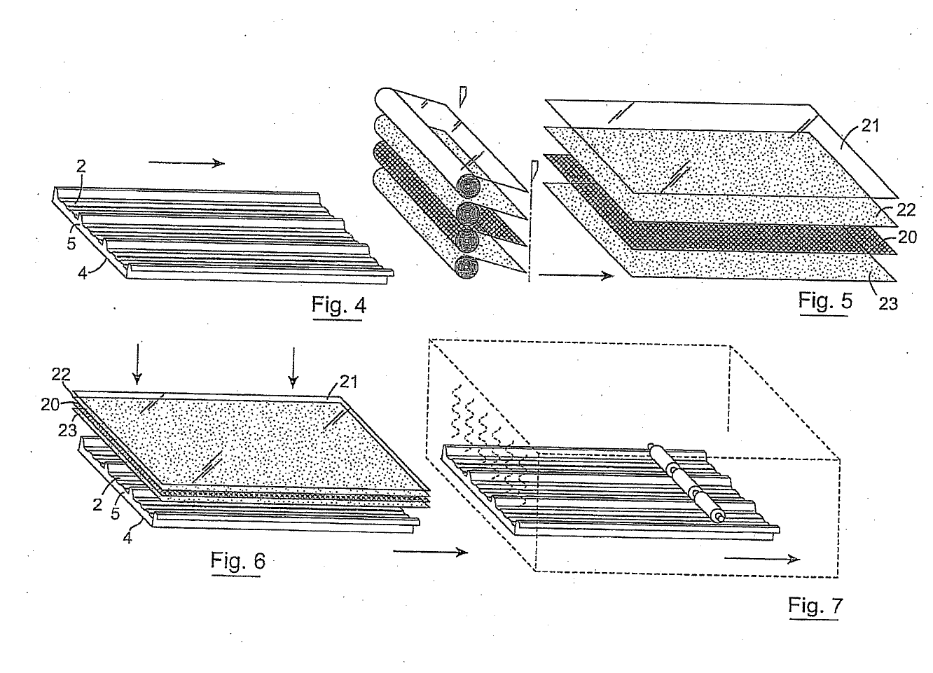

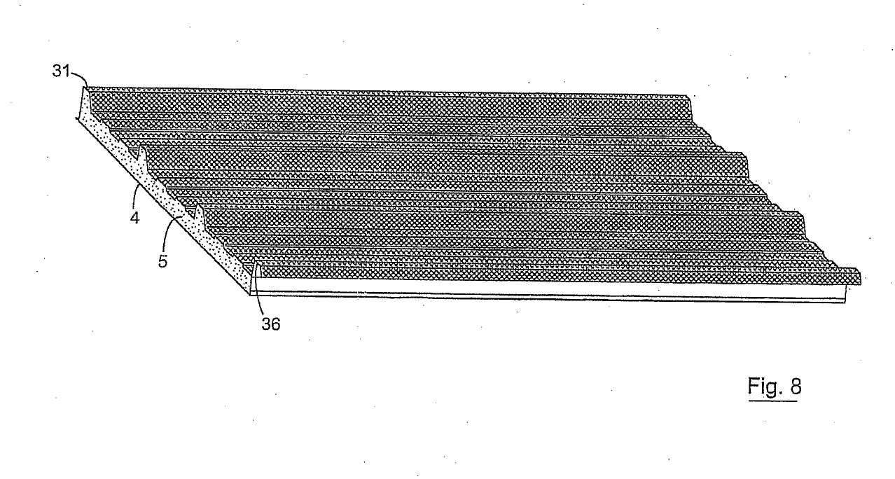

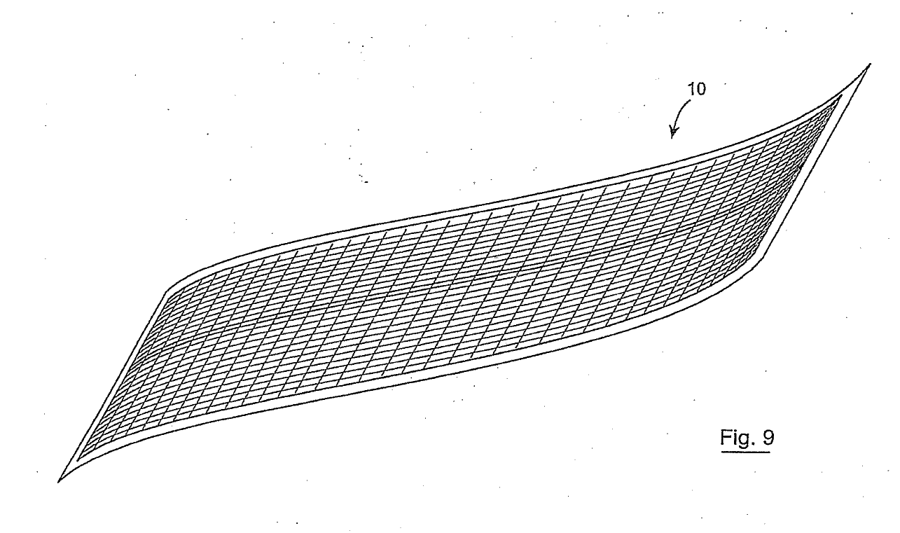

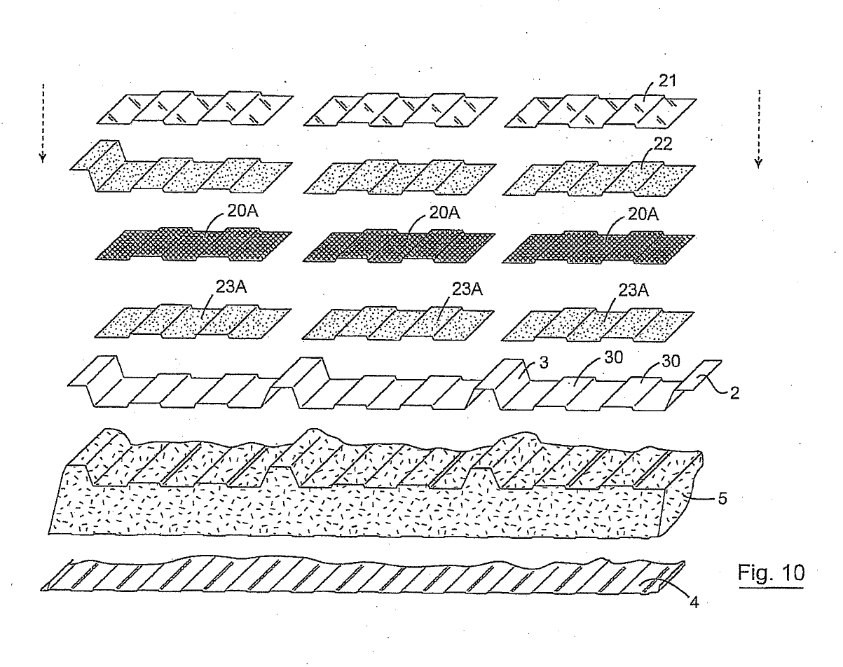

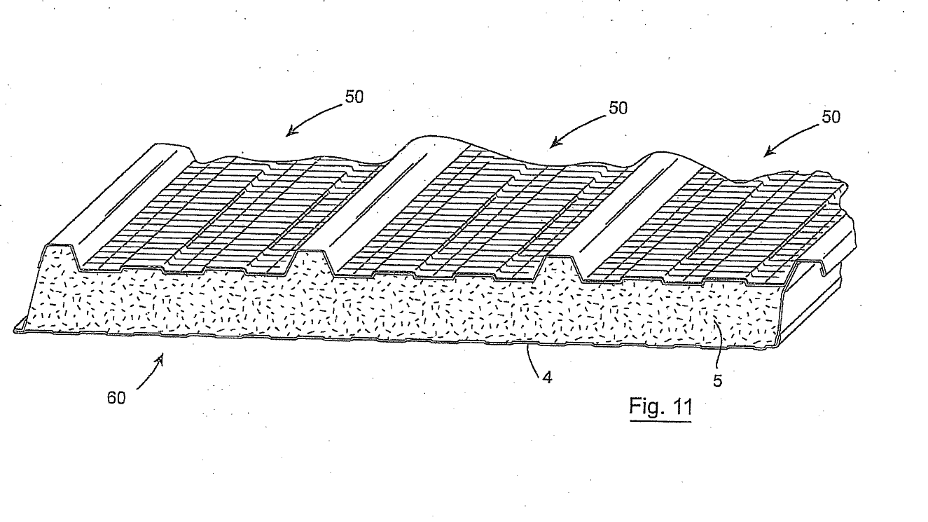

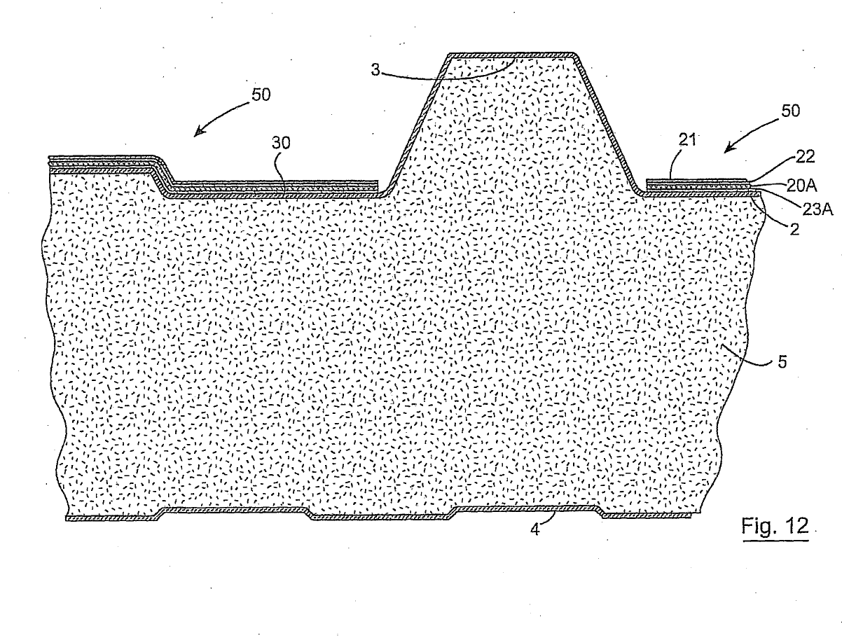

Referring to FIGS. 10 to 12 there is illustrated another panel according to the invention in which parts similar to those of FIGS. 1 to 9 are assigned the same reference numerals.

In this case the photovoltaic sheet comprises a number of elongate strips 20A which are laminated to the external sheet 2 of the panel intermediate the crowns 3. The strips 20A follow the contour of the external sheet 2 and in particular the profile of the reinforcing ribs 30. Because the photovoltaic sheet 20A does not in this case extend over the crowns 3 the panels are more easily manufactured and are less costly. In particular, as the photovoltaic sheet does not extend over the raised crowns projections it is easier to laminate to the external sheet of the panel. The photovoltaic sheets located between the raised crowns are readily electrically interconnected, for example by flexible wires/connections extending over the raised crowns. There may be a small difference in efficiency of solar collection but this is not significant in the context of the overall efficiency of the panel.

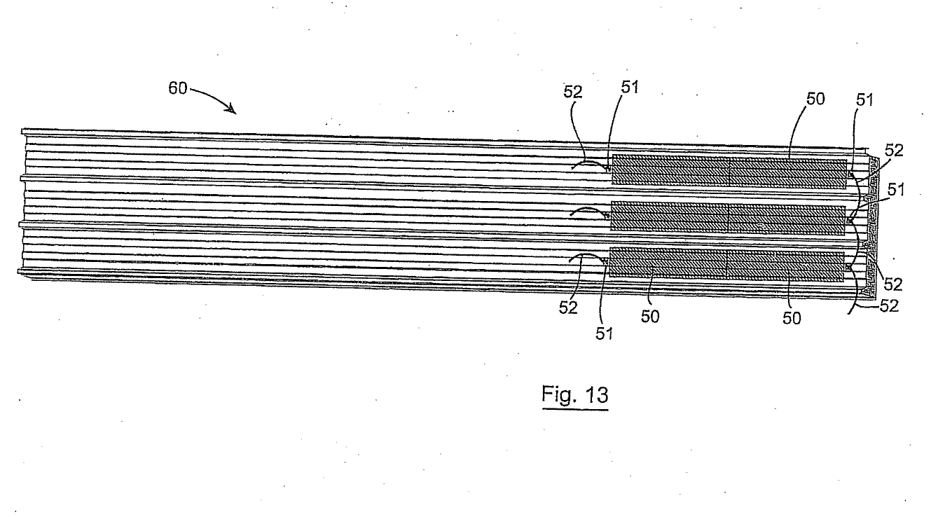

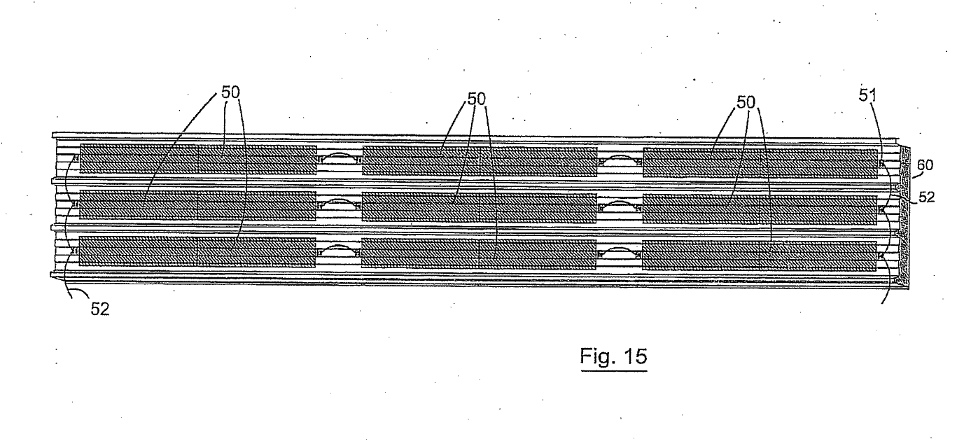

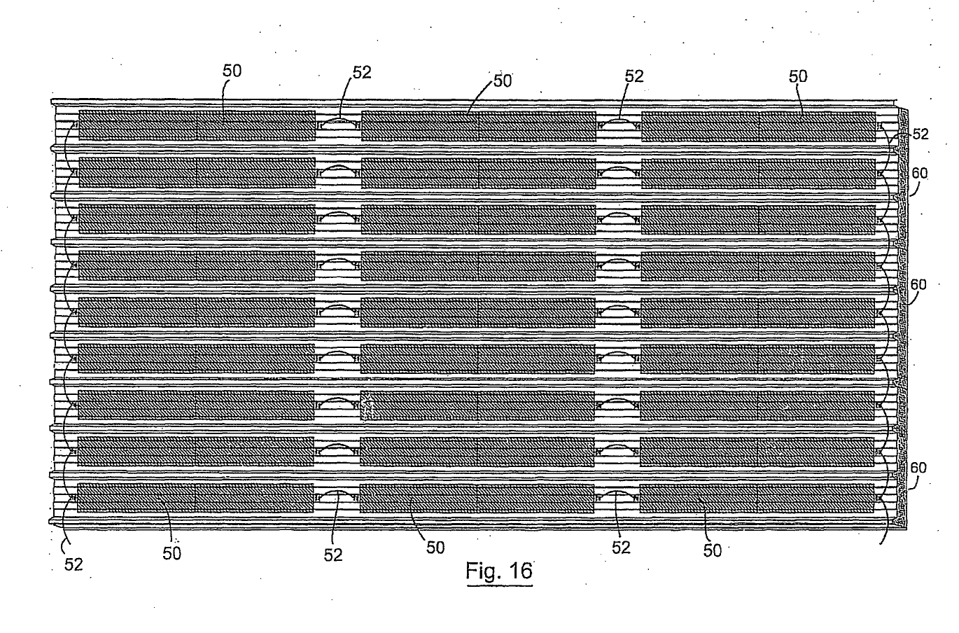

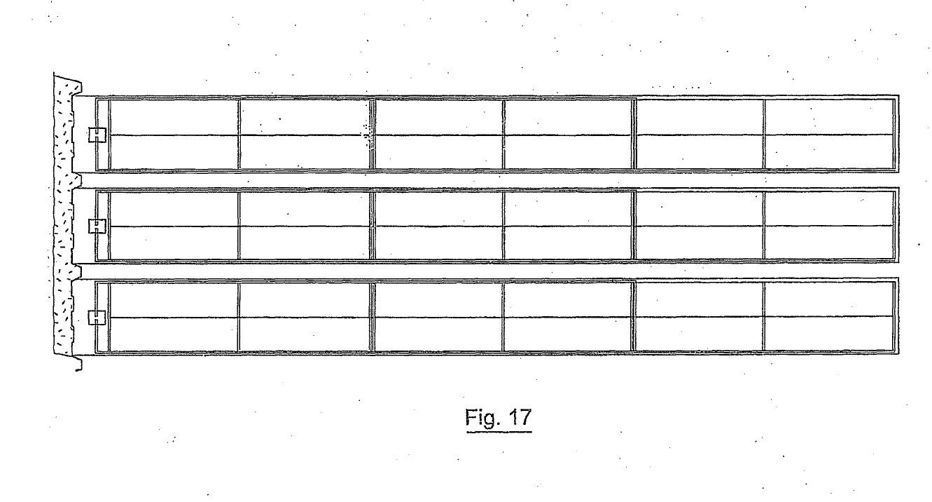

Referring to FIGS. 13 to 16 a number of separate photovoltaic solar collector units 50 are illustrated. Each of these corresponds to the photovoltaic strips 20A, adhesive layers 22, 23 and protective translucent cover layer 21. Each solar collector unit 50 has terminations 51 and adjacent solar collector units 50 are electrically interconnected by connecting links 52. In a first stage a number (in this case three) separate solar collector units 50 are laminated to the external sheet 2 of an insulating panel at one end as described above. The photovoltaic units 50 are electrically interconnected either before or after lamination forming a solar collector module comprising three units 50 (FIG. 13).

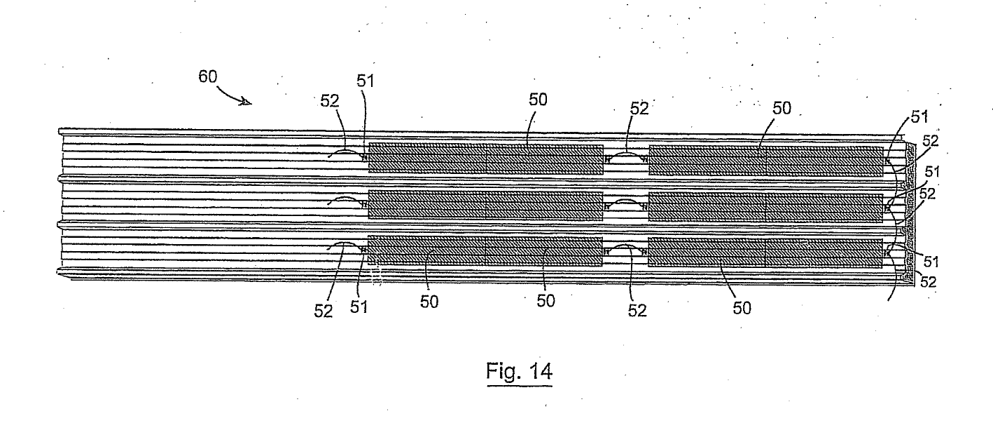

The insulating panel with the first solar collector module in situ is then indexed through a laminator and in the same way a second photovoltaic solar collector module of three units 50 is then laminated to the external sheet 2 of the insulating panel (FIG. 14).

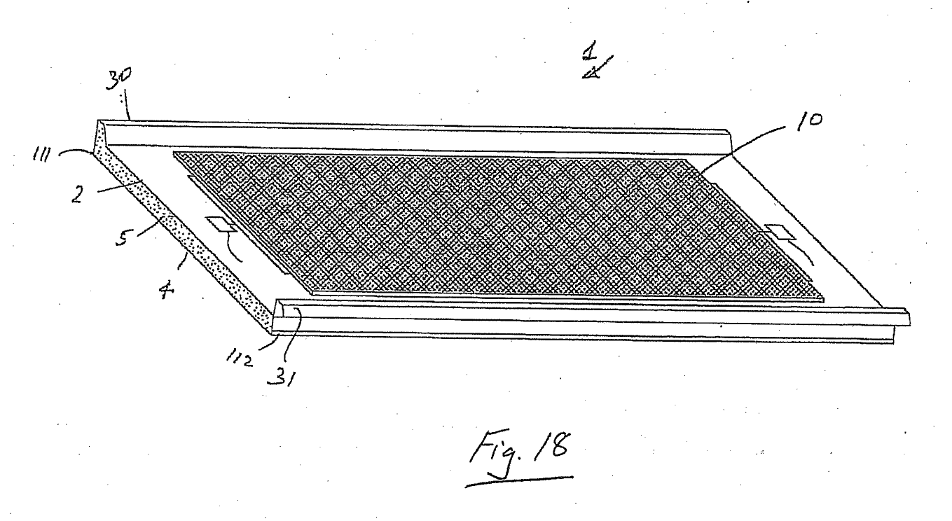

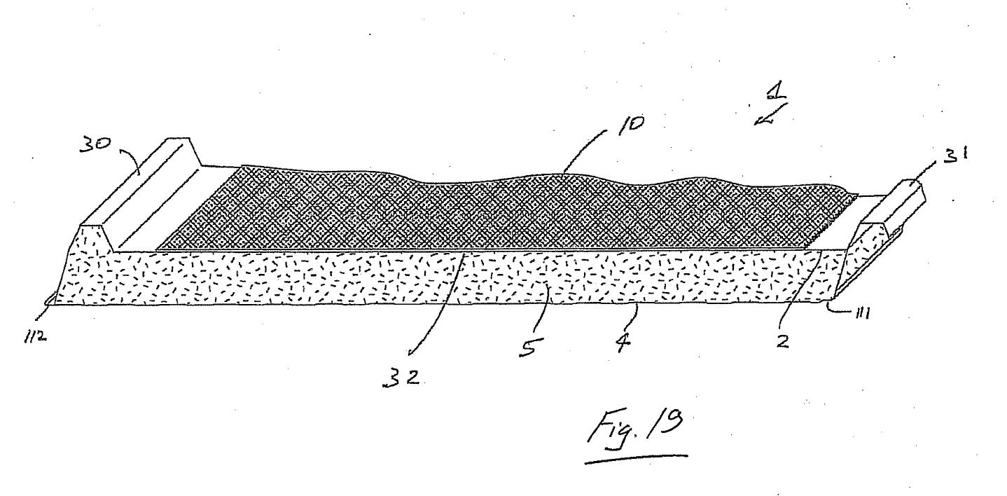

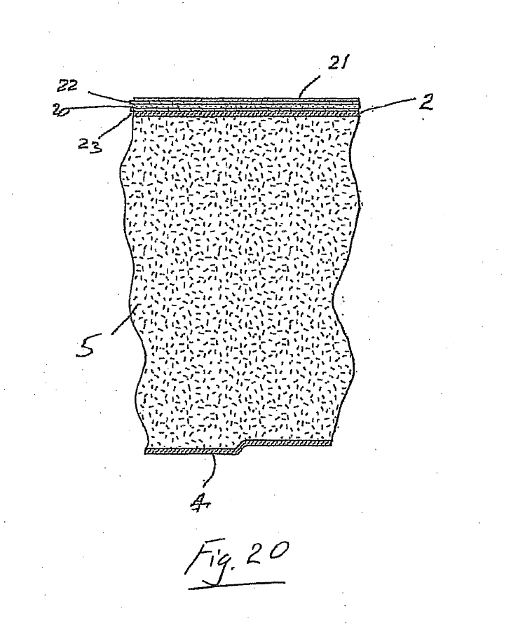

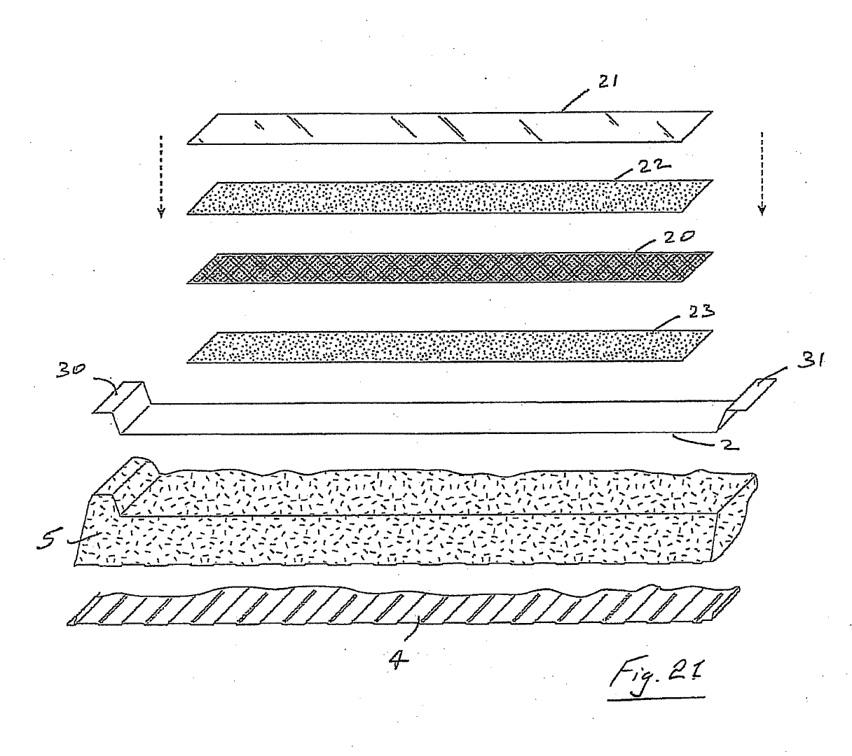

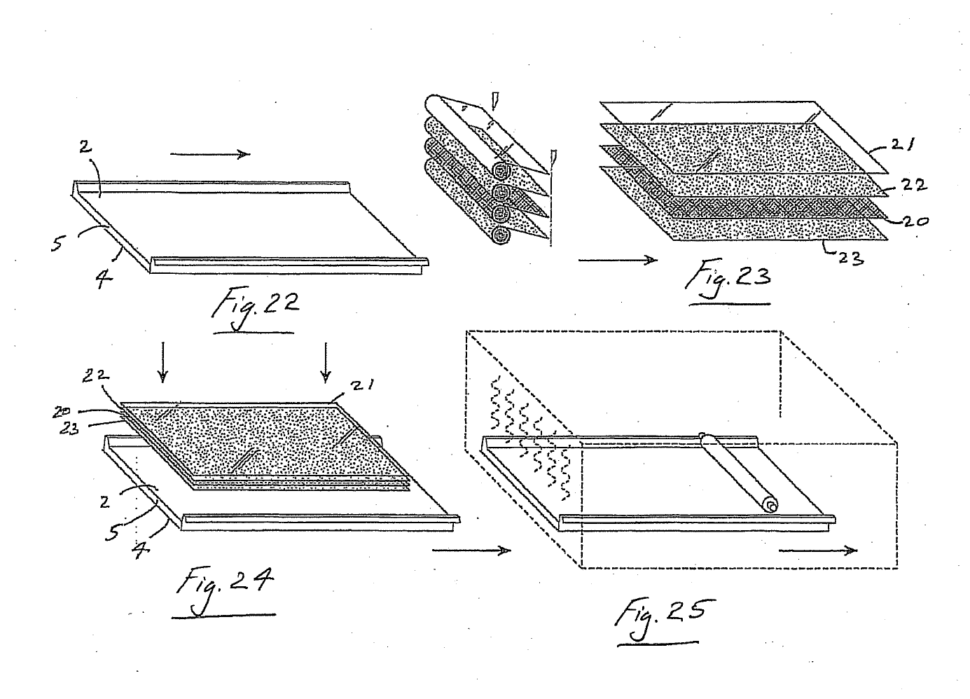

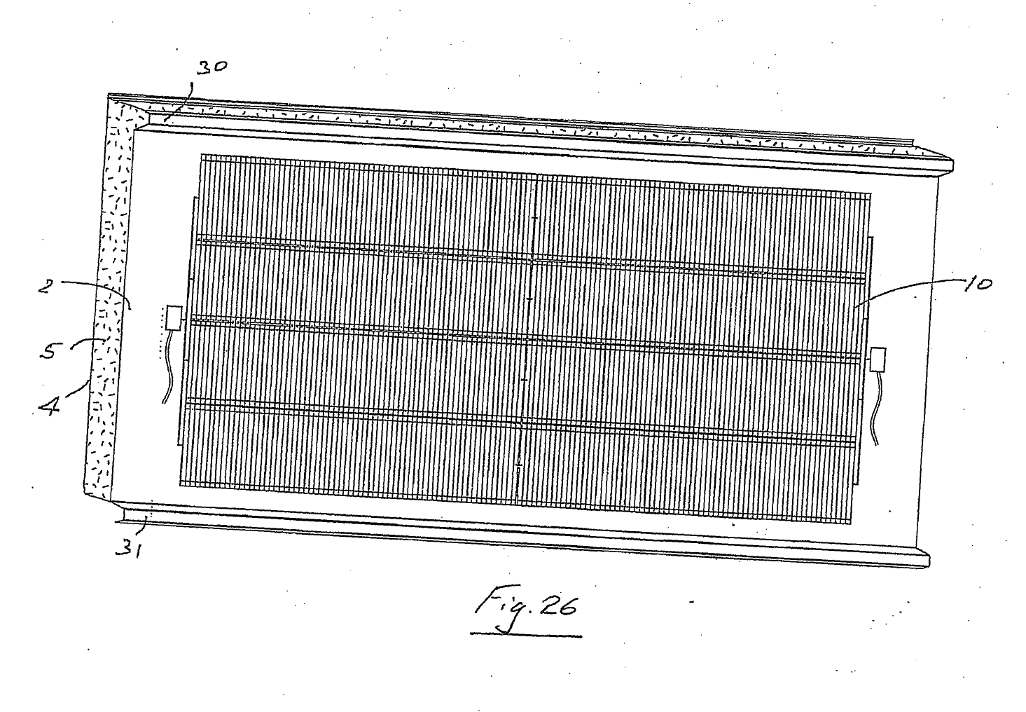

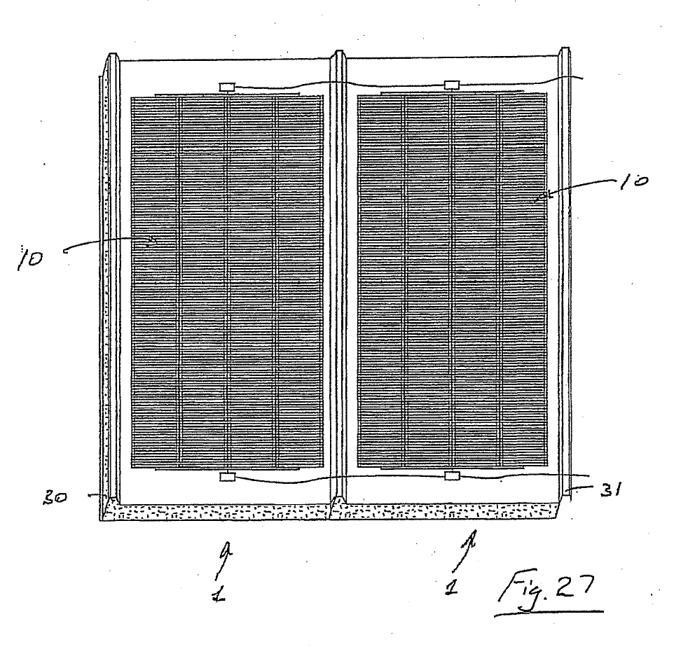

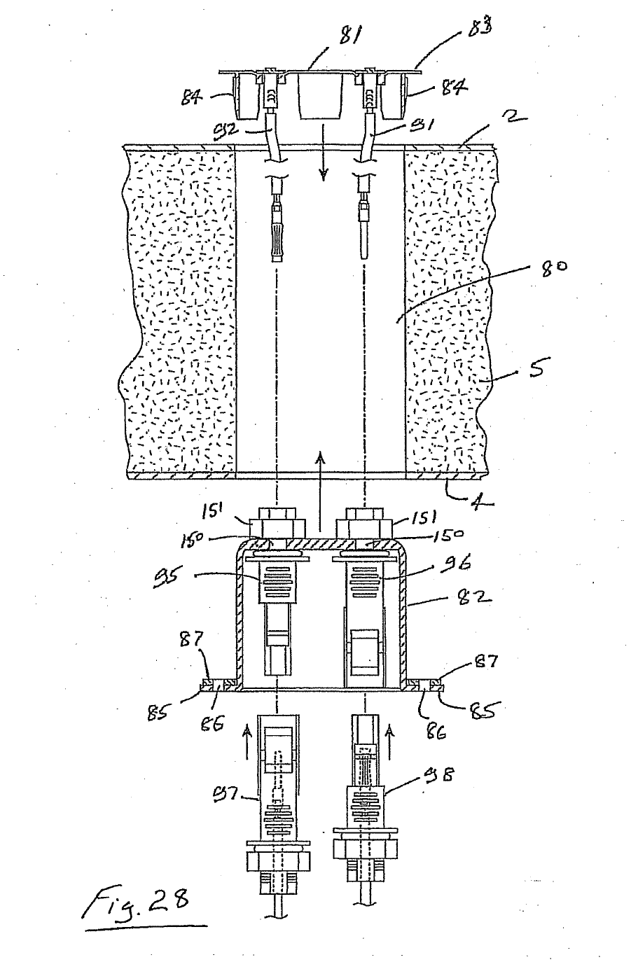

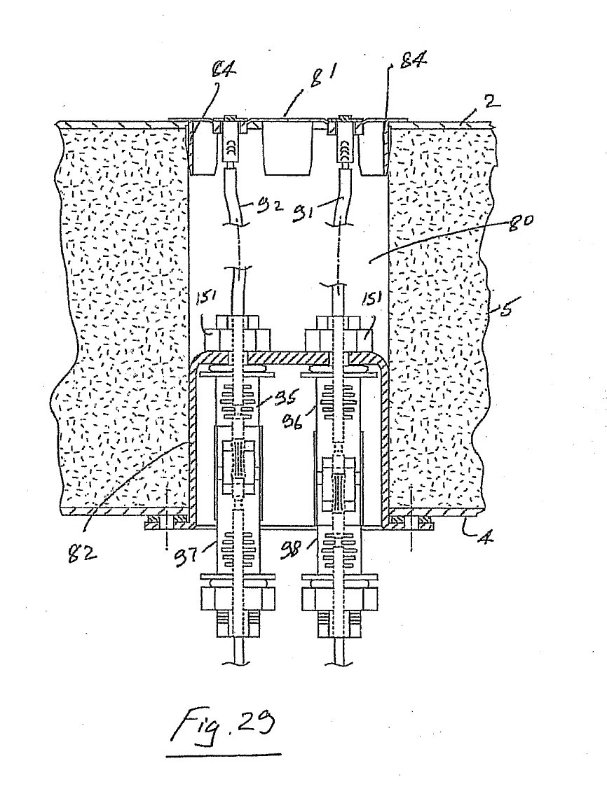

Referring to FIGS. 18 to 27 of the drawings there is illustrated an insulating panel 1 according to the invention which in this case comprises a first or external sheet 2, a second or inner sheet 4 with an insulating body, in this case an insulating foam 5 therebetween. The foam may, for example be a polyisocyanurate foam or a phenolic foam. In this case the panel 1 is a roof panel 1 comprising a profiled external sheet 2 which is typically of metal, such as galvanised steel. The external sheet 2 has a first longitudinally extending raised projection 30 at one side of the panel and a second longitudinally extending raised projection 31 on the opposite side of the panel. The external sheet 2 has a substantially flat portion 32 which extends between the first and second raised projections 30,31. The raised projections 30, 31 are in the form of crowns which in this case are of generally trapezoidal form and extend longitudinally along the length of the panel. There is a side underlap projection or crown 30 on one side of the upper sheet 2 and a side overlap projection or crown 31 on the opposite side of the panel. The projection 31 extends beyond the internal sheet 2 and the insulating body 5 to define a side overlap for overlapping with the raised projection 30 of an adjacent panel. In use, adjacent like panels are overlapped by overlapping the overlap crown 31 of one panel with the underlap crown 30 of an adjacent panel. Similarly, the panels typically have end underlap and overlap features for end lapping of adjacent like panels. The inner metal liner sheet 4 may be of metal such as steel which may be painted and/or galvanised.

The panel may have engagement formations in the form of recesses 111 and projections 112 for engagement of adjacent like panels. Such interengagement features may be provided by either the external panel sheet and/or the internal panel sheet. Interengagement features may be provided on any of the panels of the invention.

A photovoltaic solar collector unit 10 is laminated to the flat portion 32 of the external sheet 2 of the underlying insulating panel. The solar collector 10 comprises a sheet 20 comprising an array of photovoltaic elements and a translucent cover 21 for the photovoltaic sheet 20. A first adhesive layer 22 is provided between the photovoltaic sheet 20 and the translucent cover 21. A second adhesive layer 23 is provided between the underside of the photovoltaic sheet 20 and the external surface of the composite panel upper or external sheet 2. The cover 21 is of a suitable protective plastics material such as ethylene tetrafluoroethylene (ETFE) which has a high melting temperature and excellent chemical and electrical resistance properties. It is resilient and self cleaning compared to glass, an ETFE film transmits more light and costs substantially less.

The adhesive layers are preferably of a hot melt adhesive to facilitate lamination. In one case the adhesive layer 22 is of ethylene vinyl acetate (EVA).

For enhanced bond strength the adhesive layer 23 between the external sheet 2 and the photovoltaic sheet 20 comprises a thermoplastic polyurethane (TPU) material.

The flat portion preferably does not have any indentations or raised areas. Thus, the use of longitudinally extending microribs on the exposed face of the external sheet 2 is avoided. As a result, during lamination enhanced and uniform bonding between the photovoltaic sheet and the outer face of the external sheet is achieved.

Preferably the flat portion extends completely between the raised projections on the sides of the panel in order to maximise the area to which photovoltaic material is provided and exposed to sunlight. In this way the solar energy collecting efficiency of the panel is enhanced

It will be appreciated that the photovoltaic material may be of any suitable type such as amorphous silicon or crystalline silicon material.

The panel of the invention also has the advantage that a large amount of photovoltaic material can be laminated to it in one lamination step. This is important, not only in providing manufacturing efficiencies, but also in ensuring that the maximum practical amount of the face of the panel exposed to sunlight is covered by photovoltaic material. At the same time panel side overlap features are provided for underlapping with like panels for ease of assembly, on site.

The composite panel may be manufactured by a process as described in our GB 2309412 A, the entire contents of which are herein incorporated by reference.

The panels are manufactured with the external sheet 2 lowermost. For the next steps in the process of the invention the panels are turned so that the external sheet 2 is uppermost.

In the invention sheets of the photovoltaic 20, the adhesives 22, 23, and the cover 21 are drawn from supply reels, are cut to length, and then laid on top of the flat portion 32 of the upper sheet 2 of the insulated panel. Using a pressure laminating process the various layers are heated and pressed to adhere to the flat portion 32 of the outer sheet 2 of the insulated panel.

In the invention, rather than utilising a pre-prepared photovoltaic laminate assembly, some elements of the photovoltaic assembly are used individually and the assembly is laminated to the composite insulating panel in one step. In the invention a separate carrier for the photovoltaic is not required as the photovoltaic is bonded directly to the external sheet of the composite insulating panel.

Because the photovoltaic sheet does not in this case extend over the crowns 30, 31 the panels are more easily manufactured and are less costly. In particular, as the photovoltaic sheet does not extend over the raised crown projections and is applied only to the flat portion 32 between the overlap/underlap crowns 30, 31 it is easier to laminate to the external sheet of the panel. In addition, the maximum roof area is provided for a photovoltaic energy converter on a roof panel. This maximises energy return for a roof footprint. The photovoltaic sheets located between the raised crowns are readily electrically interconnected, for example by flexible wires/connections.

On site, a number of the insulating panels are jointed together and the solar collector modules of adjacent panels may be interconnected for example as illustrated in FIG. 27.

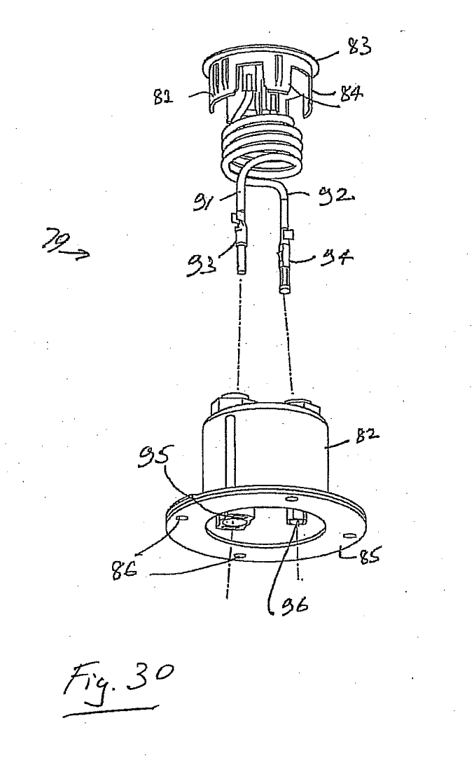

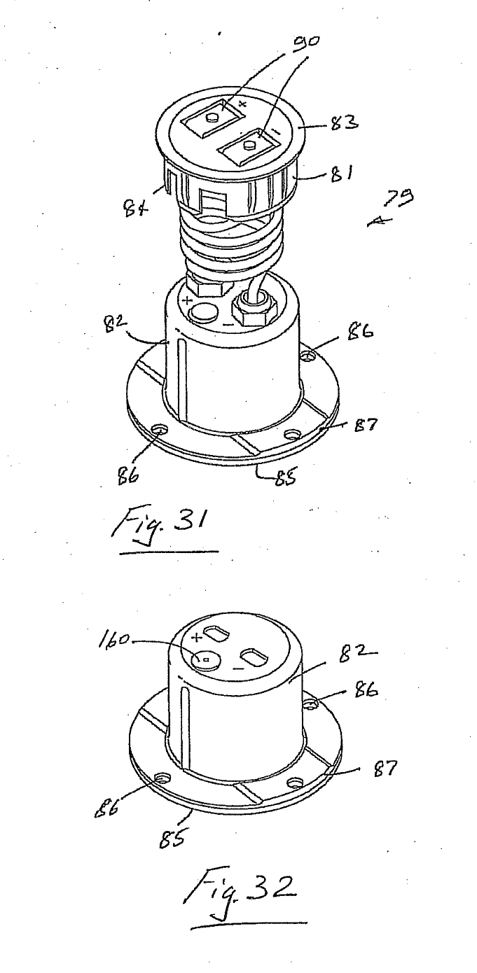

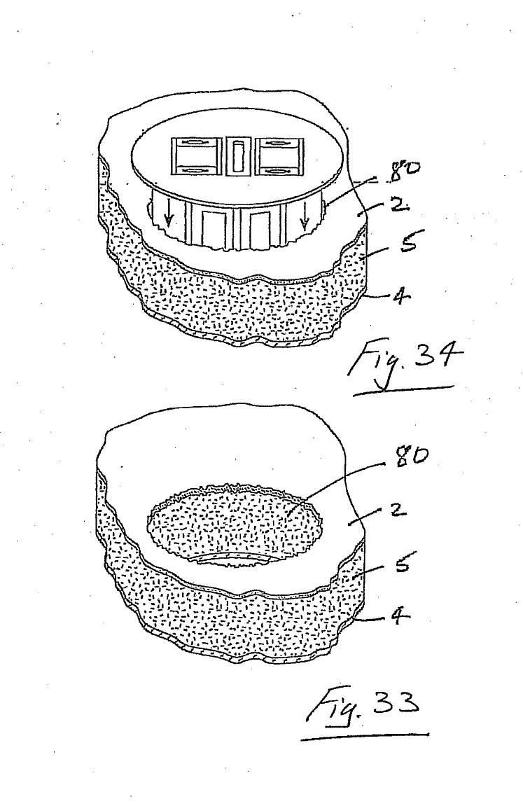

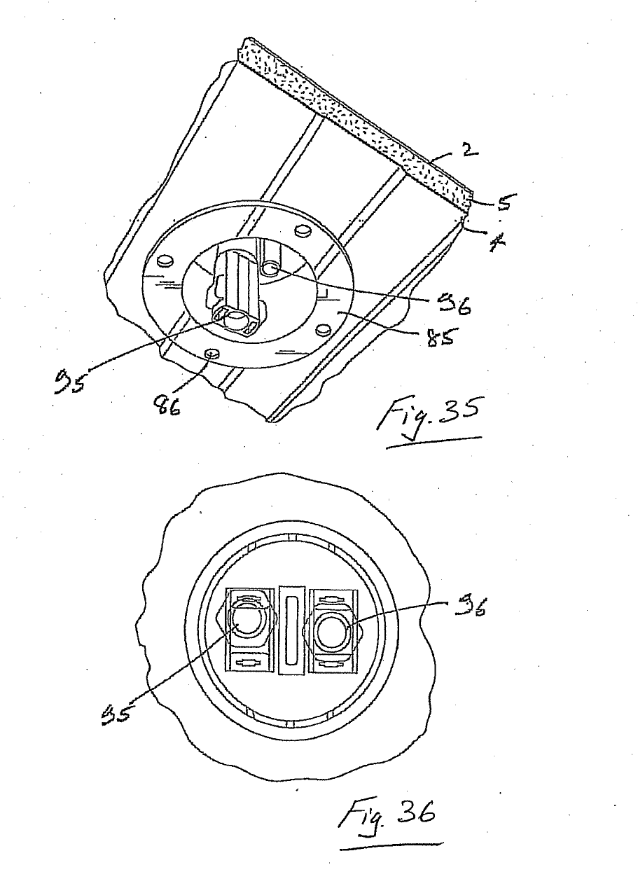

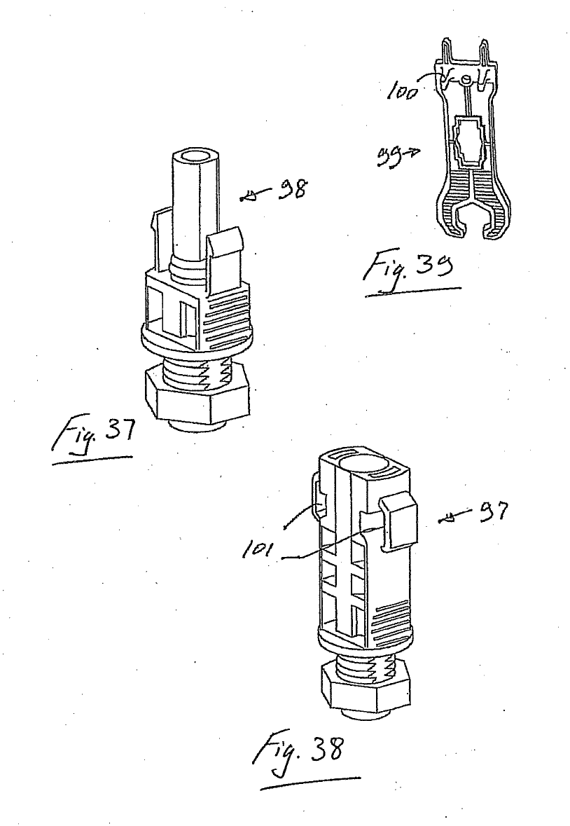

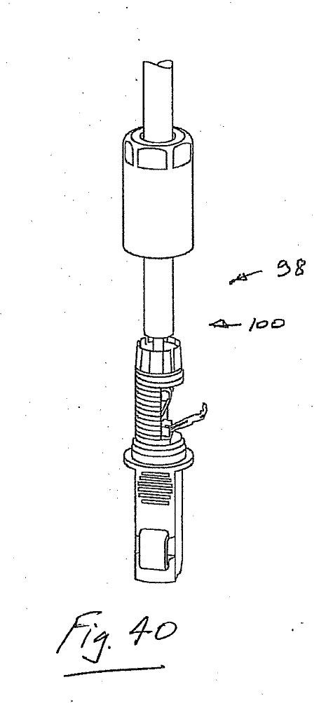

Referring to FIGS. 28 to 40, there is illustrated a connector 79 according to the invention for electrically interconnecting between photoelectric solar collector modules. The connector extends through a hole 80 in a panel. The hole 80 is made in the external sheet 2, the foam core 5, and the internal sheet 4. A housing for the connector in this case comprises an upper housing part 81 and a lower housing part 82 which extend respectively into the hole 80 in the panel from the external sheet 2 and the internal sheet 4.

The upper housing part has an enlarged region provided by a flange 83 to prevent the housing part 81 from passing completely through the hole 80. The upper housing part 81 also has a clipping means provided by radially projecting spring clips 84 for engagement in the panel hole 80.

The lower housing part 82 has an enlarged flange portion 85 which is engagable with the exposed surface of the internal panel sheet 4. The flange 85 in this case has fixing holes 86 through which suitable fixings such as screws may be inserted to fix the lower housing part to the inner panel sheet 4. Alternatively or additionally, the flange 85 may have an adhesive such as a doubled sided adhesive body or pad 87 to bond to the outer surface of the internal panel sheet 4. The housing part also has a vent hole which may be provided with a hydrophobic material 160.

The connector comprises external terminals 90 for connection to a photovoltaic module using busbar strips. Wires 91, 92 extend from the terminals 90 and are terminated at the opposite (inner) end with DC terminals 93, 94. The terminals 93, 94 extend from the upper housing part and are connected to sockets 95, 96 in the lower housing part. The sockets 95, 96 are retained in position in the housing 82 by ends which extend through holes 150 in the housing 82 and are locked using nuts 151. The sockets 95, 96 are in turn releasably attachable to connectors 97, 98 interconnect with another PV module or the like. A locking latch may be provided for the connectors 97, 98 which may be released/locked from the sockets 95, 96 by a field service tool 99. For example, projections 100 of the tool 99 may be engagable in recesses 101 of the connectors 97.

Referring to FIG. 30 it will be noted that the cables 91, 92 are wound into a spiral form. This allows the same connector to be used with any described thickness of panel.

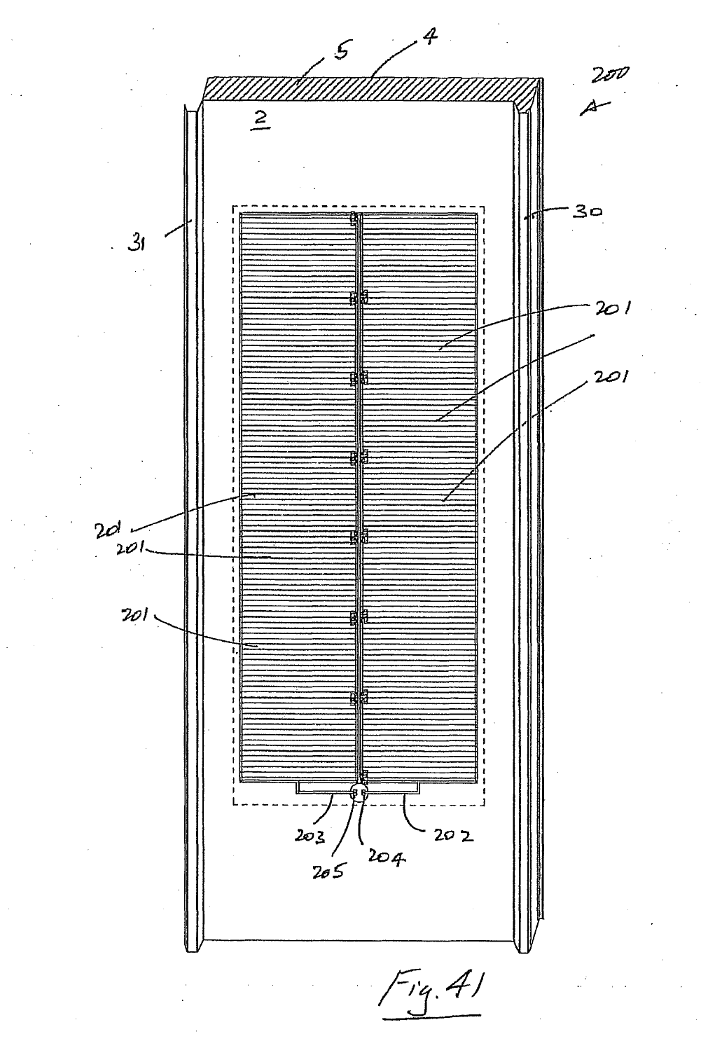

Referring to FIG. 40 there is illustrated a field attachable DC connector 98 that can be used for connection to the panels. No wire crimping is required. The field attachable connectors mate with a connector on the internal face of the panel allowing the modules to be interconnected and fed back to invertors for conversion from a DC voltage to an AC voltage for export to the electrical grid or use on a building itself.

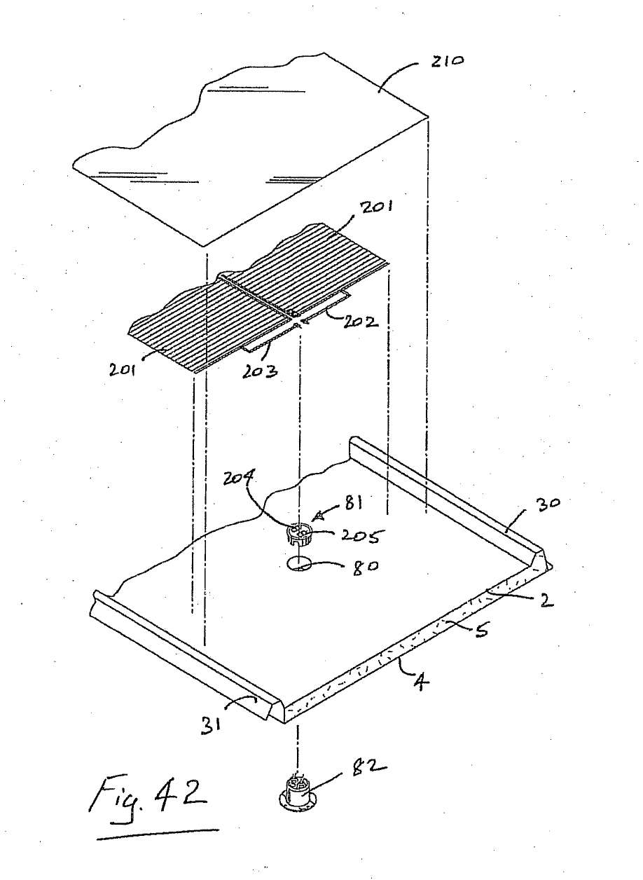

Referring to FIGS. 41 and 42 there is illustrated another composite panel 200 according to the invention which has parts similar to those described above and like parts are assigned the same reference numerals. These figures illustrate a connector 79 as described above in situ. In this case there are several interconnected photovoltaic cells 201 with positive and negative terminal strips 202, 203 respectively which are fixed, for example, by soldering to positive and negative foil terminals 204, 205 respectively mounted to the top cover part 81 of the connector 79.

In manufacture, a hole 80 is drilled in the panel 200 and the top cover part 81 of the connector 79 is inserted as illustrated and described above with reference to FIGS. 33 and 34. The assembly of interconnected photovoltaic cells are then soldered to the connector terminals/tabs 204, 205. An upper protective layer 210 is then led over the assembly of photovoltaic cells and the top of the connector. The assembly is then laminated as described above. It will be noted that the protective layer 210 extends beyond the periphery of the photovoltaic cells to ensure sealing to the exposed face of the external sheet of the panel. In particular, it will be noted that the protective layer 210 extends over the connections between the connector 79 and the array of photovoltaic cells. The lamination extending over the top part of the connector provides an enhanced weather protection without a requirement for on-site sealing. Only a single connector 79 is required to provide electrical connections to the entire photovoltaic array carried by the panel.

One advantage of the composite panel of the invention is that a photovoltaic material is incorporated as part of the manufacturing process. Thus, no additional work is required on site—the panel is fitted in exactly the same manner as a conventional composite panel. Because at least the outer part of the connector is integrated into the panel during manufacture, no roof access is required for electrical interconnection on site. This ensures a safe working environment and reduces costs considerably as safety barriers such as roof edge protectors are not required. Electrical interconnection is internal and not exposed to weathering. Electrical interconnection can be done at the same time as the building electrical fit out, thus saving costs and time. There is no risk of wire fouling during future roof maintenance. No external cable trays are required, again reducing material and labour costs. Further interconnection maintenance is facilitated from the inside of the building, no roof access is required.

The connector of the invention provides a quick and easy electrical interconnection system between PV modules. Importantly, on site, the connections can be made from the inside of a building once installed, there is no need to access from the roof above.

The photovoltaic roofing panels of the invention may be connected to an electrical system using known technologies.

It will be appreciated that the invention may be applied to a wide range of panels including roof panels, wall panels, and/or floor panels. Maximum solar efficiency is however generally achieved by covering south facing portions of a building with roof panels of the invention.

Various aspects described with reference to one embodiment may be utilised, as appropriate, with another embodiment.

Many variations on the embodiments described will be readily apparent. Accordingly the invention is not limited to the embodiments hereinbefore described which may be varied in detail.

1-33. (canceled)

32. A composite insulating panel comprising:
an external sheet;
an internal sheet;
an insulating body between the external sheet and the internal sheet,
a photovoltaic solar collector module on the external surface of the external sheet, and
a connector for interconnecting between the photovoltaic solar collector module and another photovoltaic solar collector module, and
a housing for the connector,
the panel having a through hole for receiving the housing.

33. The panel as claimed in claim 32 wherein the housing comprises an external part which extends into the panel hole from the external sheet and an internal part which extends into the panel hole from the internal sheet.

34. The panel as claimed in claim 33 wherein the external housing part has means to prevent the housing part from passing completely through the hole in the panel.

35. The panel as claimed in claim 34 wherein the means comprises a flange.

36. The panel as claimed in claim 33 wherein the external housing part has clipping means for engagement in the panel hole.

37. The panel as claimed in claim 33 wherein the internal housing part has means to prevent the housing part from passing completely through the hole in the panel.

38. The panel as claimed in claim 37 wherein the means comprises a flange.

39. The panel as claimed in claim 32 wherein the connector comprises external terminals for connection with photovoltaic cells and wire connections extending through the panel from the terminals.

40. The panel as claimed in claim 39 wherein the wires have a spiral form

41. The panel as claimed in claim 32 wherein the connector comprises internal terminals.

42. The panel as claimed in claim 41 wherein the connector comprises internal sockets to which the internal terminals are connected.

43. The panel as claimed in claim 32 comprising a plurality of photovoltaic solar collector sheets laminated to the external sheet of the panel.

44. The panel as claimed in claim 43 wherein the photovoltaic sheets are spaced-apart alone and/or across the external sheet of the panel, at least some of the photovoltaic sheets being electrically interconnected.

45. The panel as claimed in claim 39 wherein the external terminals of the connector are overlayed by a cover layer.

46. The panel as claimed in claim 32 wherein the external sheet of the panel comprises a plurality of raised projections and the photovoltaic sheets are located between the projections.

47. The panel as claimed in claim 46 wherein the raised projections extend longitudinally along the length of the panel.

48. The panel as claimed in claim 46 wherein the raised projections comprise raised crowns.

49. The panel as claimed in claim 48 wherein the raised crowns are of generally trapezoidal form.

50. The panel as claimed in claim 44 wherein the raised projections comprise a side underlap projection and a side overlap projection for jointing adjacent panels.

51. The panel as claimed in claim 32 wherein:
the external sheet comprises a first longitudinally extending raised projection at one side of the panel, a second longitudinally extending raised projection, at an opposite side of the panel and a substantially flat portion extending between the first and second raised projection; and
wherein the a photovoltaic solar collector sheet is laminated to the external surface of the flat portion of the external sheet.

52. The panel as claimed in claim 32 wherein the external sheet comprises a male projecting part and a female recess part for jointing adjacent panels.

53. The panel as claimed in claim 32 wherein the internal sheet comprises a male projecting part and a female recess part for jointing adjacent panels.

54. The panel as claimed in claim 32 wherein the insulating body comprises a foam.

55. The panel as claimed in claim 54 wherein the foam comprises a polyisocyanurate foam material or a phenolic foam material.

56. The panel as claimed in claim 32 wherein the external sheet or the internal sheet comprises a steel material.

57. The panel as claimed in claim 32 wherein the internal sheet comprises a metallic material.

58. The panel as claimed in claim 32 wherein the panel comprises a roof panel.

59. A roof assembly comprising a plurality of panels which are composite insulating panels each comprising:
an external sheet;
an internal sheet;
an insulating body between the external sheet and the internal sheet,
a photovoltaic solar collector module on the external surface of the external sheet, and
a connector for interconnecting between the photovoltaic solar collector module and another photovoltaic solar collector module, and
a housing for the connector,
the panel having a through hole for receiving the housing.
